(19) United States
(12) Patent Application Publication
(10) Pub. No.: US 2024/0194807 A1
(43) Pub. Date: Jun. 13, 2024

(54) PHOTOELECTRIC CONVERSION ELEMENT, METHOD FOR MANUFACTURING THE SAME, AND IMAGING DEVICE

(71) Applicant: SONY SEMICONDUCTOR SOLUTIONS CORPORATION, KANAGAWA (JP)

(72) Inventor: HARUYUKI NAKAGAWA, KANAGAWA (JP)

(21) Appl. No.: 18/550,419

(22) PCT Filed: Feb. 17, 2022
(86) PCT No.: PCT/JP2022/006473

§ 371 Date: Sep. 13, 2023

(30) Foreign Application Priority Data
Mar. 25, 2021 (JP) 2021-051422

(51) Int. Cl. H01L 31/0304; H01L 27/146; H01L 31/18

(52) U.S. Cl. CPC H01L 31/03046; H01L 27/14605; H01L 31/1844

(57) ABSTRACT

To provide a photoelectric conversion element capable of further suppressing color mixing, a method for manufacturing the same, and an imaging device. According to the present disclosure, there is provided a photoelectric conversion element including: a first compound semiconductor layer including a first compound semiconductor material having a first conductivity type; a photoelectric conversion layer formed in contact with the first compound semiconductor layer; a second compound semiconductor layer formed in contact with the photoelectric conversion layer and including a second compound semiconductor material having the first conductivity type; a first second conductivity type region formed on at least a part of the second compound semiconductor layer, having a second conductivity type different from the first conductivity type, and reaching the photoelectric conversion layer; and a second second conductivity type region formed on at least a part of the second compound semiconductor layer, having the second conductivity type, and reaching the photoelectric conversion layer, the second second conductivity type region having a region different from the first second conductivity type region.

### TECHNICAL FIELD

The present disclosure relates to a photoelectric conversion element, a method for manufacturing the same, and an imaging device.

### BACKGROUND ART

A current photoelectric conversion element using InGaAs can capture an image up to near-infrared (NIR) and short-wave infrared (SWIR) ranges. Therefore, it is also used in an industrial inspection apparatus in addition to general imaging.

### CITATION LIST

### Patent Document

Patent Document 1: Japanese Patent Application Laid-Open No. 2017-175102

### SUMMARY OF THE INVENTION

### Problems to be Solved by the Invention

In a case where separation cannot be performed for every pixel in a photoelectric conversion layer, there is a possibility that color mixing occurs due to movement of generated carriers to adjacent pixels. Therefore, an electric field is generated by an impurity diffusion region, and carrier convergence is improved. However, in an industrial inspection apparatus or the like, there is a case where further suppression of color mixing is required.

Therefore, the present disclosure provides a photoelectric conversion element capable of further suppressing color mixing, a method for manufacturing the same, and an imaging device.

### Solutions to Problems

in order to solve the problems described above, according to the present disclosure, there is provided a photoelectric conversion element including:
a first compound semiconductor layer including a first compound semiconductor material having a first conductivity type;
a photoelectric conversion layer formed in contact with the first compound semiconductor layer;
a second compound semiconductor layer formed in contact with the photoelectric conversion layer and including a second compound semiconductor material having the first conductivity type;
a first second conductivity type region formed in at least a part of the second compound semiconductor layer, having a second conductivity type different from the first conductivity type, and reaching the photoelectric conversion layer; and a second second conductivity type region formed in at least a part of the second compound semiconductor layer, having the second conductivity type, and reaching the photoelectric conversion layer, the second second conductivity type region having a region different from the first second conductivity type region.

A first electrode electrically connected to the first compound semiconductor layer; and
a second electrode formed on the second conductivity type regions may be further provided.

The first second conductivity type region and the second second conductivity type region may have different impurity concentrations.

The first second conductivity type region may have a lower impurity concentration than the second second conductivity type region, and the first second conductivity type region may be formed closer to the first compound semiconductor layer than the second second conductivity type region.

There may be further provided a third second conductivity type region formed on at least a part of the second compound semiconductor layer, having the second conductivity type, and reaching the photoelectric conversion layer, the third second conductivity type region having a region different from the first second conductivity type region and the second second conductivity type region.

The first second conductivity type region and the second second conductivity type region may be formed by diffusing impurities under different conditions.

The first second conductivity type region and the second second conductivity type region may be formed by diffusing the impurities from different positions.

The first second conductivity type region may have a higher impurity concentration than the second second conductivity type region, and may be formed closer to the first compound semiconductor layer than the second second conductivity type region.

The second second conductivity type region may have two protruded regions along the second compound semiconductor layer.

The photoelectric conversion layer may be formed by laminating a plurality of layers having different impurity concentrations.

The first electrode may be formed on a surface of the first compound semiconductor layer on a light incident side.

The first compound semiconductor layer and the second compound semiconductor layer may include the same material.

The first compound semiconductor layer and the second compound semiconductor layer may include a group III-V compound semiconductor material.

The photoelectric conversion layer may include InGaAs, and the first compound semiconductor layer and the second compound semiconductor layer may include InP.

Light may be incident through the first compound semiconductor layer.

In an imaging device, a plurality of the photoelectric conversion elements may be arranged in a two-dimensional matrix.

According to the present disclosure, a method for manufacturing a photoelectric conversion element including the steps of:
sequentially forming a first compound semiconductor layer including a first compound semiconductor material having a first conductivity type, a photoelectric conversion layer, and a second compound semiconductor layer including a second compound semiconductor material having the first conductivity type;
forming, on at least a part of the second compound semiconductor layer, a first second conductivity type region having a second conductivity type different from the first conductivity type and reaching the photoelectric conversion layer; and
forming, on at least a part of the second compound semiconductor layer, a second second conductivity type region having the second conductivity type and reaching the photoelectric conversion layer under a condition different from a condition of the first second conductivity type region.

The first second conductivity type region and the second second conductivity type region may be formed by diffusing impurities from the second compound semiconductor layer via a mask layer.

The second second conductivity type region may be formed by diffusing impurities from the second compound semiconductor layer via a first mask layer, removing the first mask layer, and then diffusing impurities via a second mask layer.

A state in which the impurities are diffused via the first mask layer may be different from a state in which the impurities are diffused via the second mask layer in at least any one of an impurity concentration, a temperature, and a time.

### BRIEF DESCRIPTION OF DRAWINGS

FIG. 1 is a diagram illustrating a configuration example of an imaging device according to a first embodiment.

FIG. 2 is a schematic partial cross-sectional view of a photoelectric conversion element according to the present embodiment.

FIG. 3 is a diagram illustrating a relationship between positions and concentrations of a first second conductivity type region and a second second conductivity type region.

FIG. 4 is a schematic partial cross-sectional view of a photoelectric conversion element according to a comparative example.

FIG. 5 is a schematic view illustrating a step of generating the first second conductivity type region and the second second conductivity type region.

FIG. 6 is a plan view of a mask layer used for generating the first second conductivity type region.

FIG. 7 is a plan view of a mask layer used for generating the second second conductivity type region.

FIG. 8 is a schematic view illustrating a step of generating a first electrode and a second electrode.

FIG. 9 is a schematic partial cross-sectional view of a photoelectric conversion element according to a second embodiment.

FIG. 10 is a diagram illustrating a relationship between positions and concentrations of first to third second conductivity type regions.

FIG. 11 is a schematic view illustrating a step of generating the first to third second conductivity type regions.

FIG. 12 is a plan view of a mask layer used for generating the third second conductivity type region.

FIG. 13 is a schematic partial cross-sectional view of a photoelectric conversion element according to a third embodiment.

FIG. 14 is a diagram illustrating a relationship between positions and concentrations of fourth and fifth second conductivity type regions.

FIG. 15 is a plan view of a mask layer used for generating the fifth second conductivity type region.

FIG. 16 is a schematic view illustrating a step of generating the fourth and fifth second conductivity type regions.

FIG. 17 is a schematic partial cross-sectional view of a photoelectric conversion element according to a fourth embodiment.

FIG. 18 is a diagram illustrating a relationship between positions and concentrations of a photoelectric conversion layer and a second second conductivity type region.

FIG. 19 is a diagram illustrating an example of a method for manufacturing the photoelectric conversion element according to the fourth embodiment.

FIG. 20 is a schematic partial cross-sectional view of a photoelectric conversion element 101 according to a fifth embodiment.

FIG. 21 is a diagram illustrating a relationship between positions and concentrations of a photoelectric conversion layer and first and second second conductivity type regions.

FIG. 22 is a diagram illustrating an example of a method for manufacturing the photoelectric conversion element according to the fifth embodiment.

FIG. 23 is a conceptual diagram illustrating an example in which the disclosed imaging device is used in an electronic apparatus.

### MODES FOR CARRYING OUT THE INVENTION

Hereinafter, embodiments of a photoelectric conversion element, a method for manufacturing the same, and an imaging device will be described with reference to the drawings. Although principal components of the photoelectric conversion element, the method for manufacturing the same, and the imaging device will be mainly described below, the photoelectric conversion element, the method for manufacturing the same, and the imaging device can include components and functions that are not illustrated or described. The following description does not exclude components and functions that are not illustrated or described.

### First Embodiment

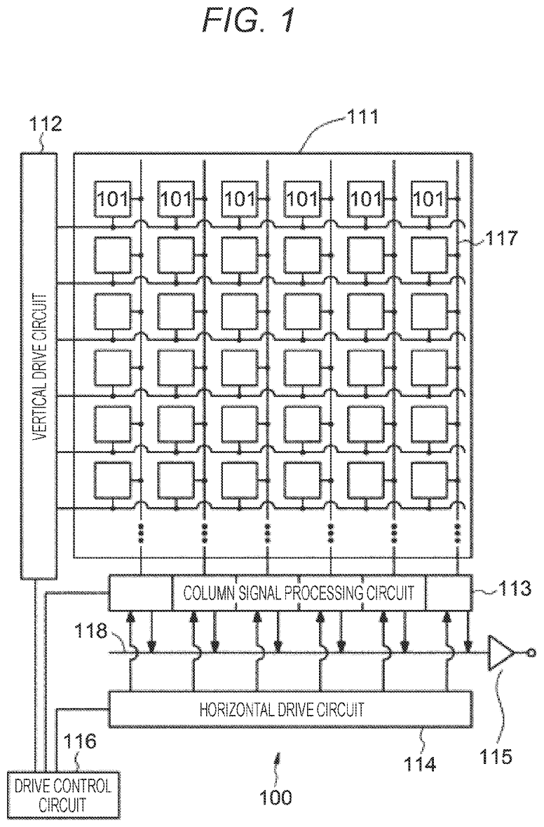

FIG. 1 is a diagram illustrating a configuration example of an imaging device 100 according to a first embodiment of the present technology. As illustrated in FIG. 1, the imaging device 100 includes an imaging region 111 in which photoelectric conversion elements 101 are arranged in a two-dimensional matrix (two-dimensional array), and a vertical drive circuit 112, a column signal processing circuit 113, a horizontal drive circuit 114, an output circuit 115, a drive control circuit 116, and the like, which are drive circuits (peripheral circuits). Note that these circuits can include known circuits, and furthermore, can be configured using other circuit configurations (for example, various circuits used in a conventional CCD imaging device or CMOS imaging device). That is, this imaging device 100 can generate an electric field in the photoelectric conversion element 101 by a Zn diffusion region of a plurality of stages to suppress color mixing between pixels.

The drive control circuit 116 generates a clock signal and a control signal serving as references for operations of the vertical drive circuit 112, the column signal processing circuit 113, and the horizontal drive circuit 114 on the basis of a vertical synchronization signal, a horizontal synchronization signal, and a master clock. Then, the generated clock signal and control signal are input to the vertical drive circuit 112, the column signal processing circuit 113, and the horizontal drive circuit 114.

The vertical drive circuit 112 includes, for example, a shift register, and selectively scans the photoelectric conversion elements 101 in the imaging region 111 sequentially in a vertical direction row by row. Then, a pixel signal (image signal) based on a current (signal) generated according to an amount of received light in each photoelectric conversion element 101 is sent to the column signal processing circuit 113 via a signal line (data output line) 117.

The column signal processing circuit 113 is arranged, for example, for each column of the photoelectric conversion elements 101, and performs signal processing of noise removal and signal amplification on the image signals output from the photoelectric conversion elements 101 for one row by a signal from a black reference pixel (not illustrated, and formed around an effective pixel region) for each imaging element. A horizontal selection switch (not illustrated) is provided at an output stage of the column signal processing circuit 113 to be connected with a horizontal signal line 118.

The horizontal drive circuit 114 includes, for example, a shift register, sequentially selects each of the column signal processing circuits 113 by sequentially outputting horizontal scanning pulses, and outputs the signal from each of the column signal processing circuits 113 to the horizontal signal line 118.

The output circuit 115 performs signal processing on the signals sequentially supplied from each of the column signal processing circuits 113 through the horizontal signal line 118 to output.

From the photoelectric conversion element 101, a charge coupled device (CCD) element, a complementary metal oxide semiconductor (CMOS) image sensor, a contact image sensor (CIS), and a charge modulation device (CMD) type signal amplification type image sensor can be configured. Furthermore, from the imaging device 100, for example, an electronic apparatus having an imaging function, such as a digital still camera, a video camera, a camcorder, an in-vehicle camera, a monitoring camera, a mobile phone, and the like can be configured. A configuration and a structure of the imaging device excluding the photoelectric conversion element can be the same as the configuration and the structure of a known imaging device, and various processing of the signal obtained by the photoelectric conversion element can also be performed on the basis of a known circuit.

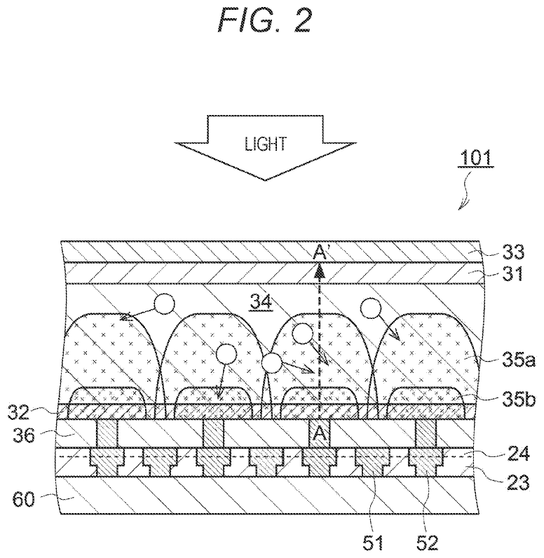

FIG. 2 is a schematic partial cross-sectional view of the photoelectric conversion element 101 according to the present embodiment. The photoelectric conversion element 101 includes, for example, a support substrate 23, an insulating film 24, a first compound semiconductor layer 31, a second compound semiconductor layer 32, a reflecting film 33, a photoelectric conversion layer 34, a first second conductivity type region 35a, a second second conductivity type region 35b, a covering layer 36, a first electrode 51, and a second electrode 52. The second electrode 52 is formed on the same side as the first electrode 51. The first electrode 51 is electrically connected to the first compound semiconductor layer 31. The second electrode 52 is electrically connected to the second conductivity type regions 35a and 35b.

As illustrated in FIG. 2, the covering layer 36, the second compound semiconductor layer 32, the photoelectric conversion layer 34, and the reflecting film 33 are laminated on the insulating film 24 formed on the support substrate 23. The imaging device 100 (see FIG. 1) of the present disclosure further includes a driving substrate 60, for example, a read only IC substrate (ROIC substrate). The first electrode 51 constituting each photoelectric conversion element 101 is connected to a first electrode connection portion provided on the driving substrate 60. In this case, the second electrode 52 constituting each photoelectric conversion element 101 is connected to a second electrode connection portion provided on the driving substrate 60.

In the present embodiment, light enters through the first compound semiconductor layer 31. The first conductivity type is an n-type, and the second conductivity type is a p-type. The first compound semiconductor layer 31 and the second compound semiconductor layer 32 include the same material. For example, the first compound semiconductor layer 31, the second compound semiconductor layer 32, and the photoelectric conversion layer 34 include a group III-V compound semiconductor material. Then, the photoelectric conversion layer 34 includes InGaAs (specifically, n-InGaAs, more specifically, n-In0.57Ga0.43As), and the first compound semiconductor layer 31 and the second compound semiconductor layer 32 include InP (specifically, n⁺-InP). For example, an impurity concentration Im0 of the photoelectric conversion layer 34 is 5×10¹⁶ cm⁻³ or less, and impurity concentrations Im1 and Im2 of the first compound semiconductor layer 31 and the second compound semiconductor layer 32 are also 5×10¹⁷ cm⁻³ to 5×10¹⁸ cm⁻³. Note that the first conductivity type may be the p-type, and the second conductivity type may be the n-type.

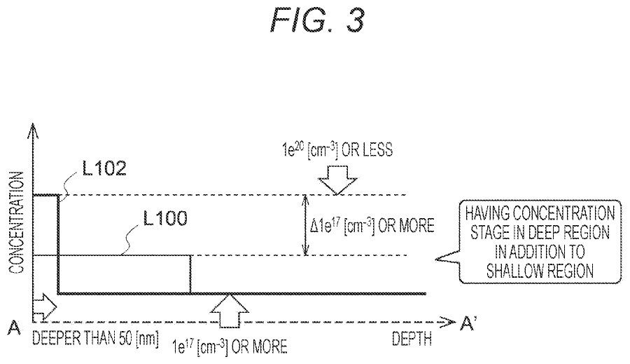

FIG. 3 is a diagram illustrating a relationship between positions and concentrations of the first second conductivity type region 35a and the second second conductivity type region 35b. The vertical axis represents concentration, and the horizontal axis represents a position on an A-A′ line (see FIG. 2). A position of a lower surface of the second compound semiconductor layer 32 is indicated by 0 as a Zn diffusion surface, and a position from the Zn diffusion surface is indicated as a depth. The first second conductivity type region 35a and the second second conductivity type region 35b are generated by, for example, Zn diffusion. A line L100 indicates a relationship between a depth and an impurity concentration of the first second conductivity type region 35a. A line L102 indicates a relationship between a depth and an impurity concentration of the second second conductivity type region 35b. As described above, the second second conductivity type region 35b having an impurity concentration of, for example, 1e²⁰ [cm⁻³] is formed deeper than 50 nm in a depth direction of a pixel center in the second compound semiconductor layer 32 and the photoelectric conversion layer 34 by two-stage Zn diffusion. Note that the second second conductivity type region 35b may be configured in a concentration range of, for example, 1e¹⁷ [cm⁻³] to 1e²⁰ [cm⁻³].

The first second conductivity type region 35a is configured to have, for example, a concentration difference of 1e¹⁷ [cm⁻³] with respect to the impurity concentration of the second second conductivity type region 35b. In this way, Zn diffusion is performed to be thin and deep, and in addition, shallow Zn diffusion is performed to have a structure in which a plurality of concentration distributions is combined.

When infrared light is incident on the photoelectric conversion element 101 from the first compound semiconductor layer 31 side, holes and electrons are generated in the photoelectric conversion layer 34. When a potential higher than that of the second electrode 52 is applied to the first electrode 51, the electrons are extracted from the first conductivity type region 31 to the outside via the first electrode 51. On the other hand, the holes are extracted from the first second conductivity type region 35a, the second second conductivity type region 35b, and the second compound semiconductor layer 32 to the outside via the second electrode 52. Since an electric field is generated at a boundary where a Z concentration difference occurs, more holes as carriers can be collected by the second electrode 52 by the first second conductivity type region 35a and the second second conductivity type region 35b. Note that, although the first electrode 51 and the second electrode 52 according to the present embodiment are provided on the same side, the present invention is not limited thereto. For example, the first electrode 51 may be provided on the first compound semiconductor layer 31 side.

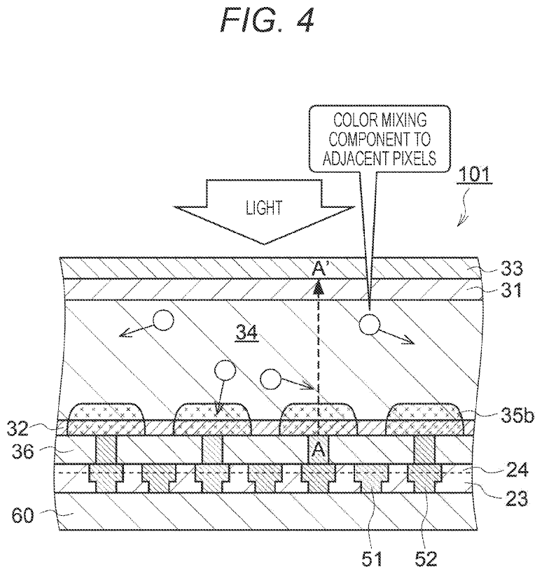

FIG. 4 is a schematic partial cross-sectional view of a photoelectric conversion element 101 according to a comparative example. The photoelectric conversion element 101 according to the comparative example is an example in which the first second conductivity type region 35a is not formed. Since the first second conductivity type region 35a is not formed, there is a high possibility that holes, which are carriers generated on an incident light side of a photoelectric conversion layer 34, move to adjacent pixels. On the other hand, since the photoelectric conversion element 101 according to the present embodiment further forms the first second conductivity type region 35a as described above, the holes, which are carriers generated on an incident light side of the photoelectric conversion layer 34, can also be collected by the second electrode 52 by the electric field generated at the boundary of the first second conductivity type region 35a, and color mixing can be further suppressed. That is, the formation of the electric field can be generated such that more carriers (for example, the holes) are collected by the second electrode 52 by forming the second conductivity type regions 35a and 35b in two stages. Therefore, carriers generated in a predetermined range (corresponding to a pixel range) above the second electrode 52 can be collected by the second electrode 52 in the same pixel.

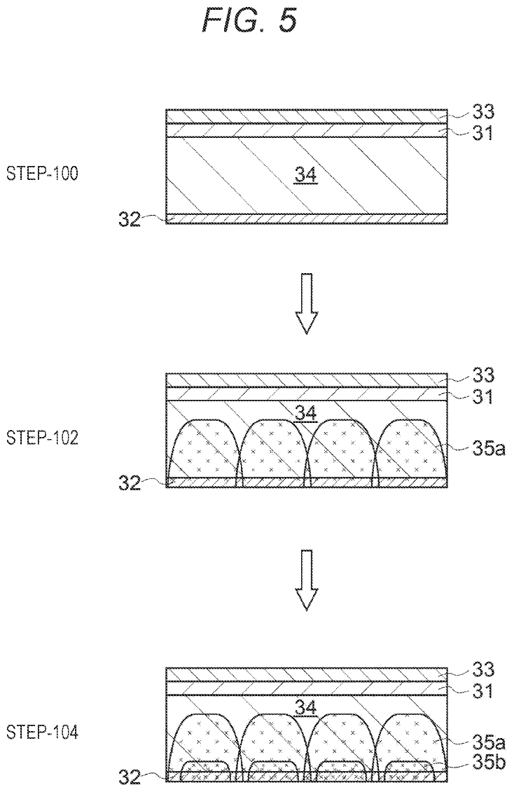

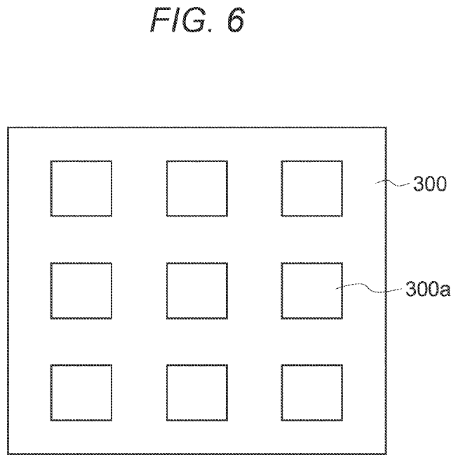

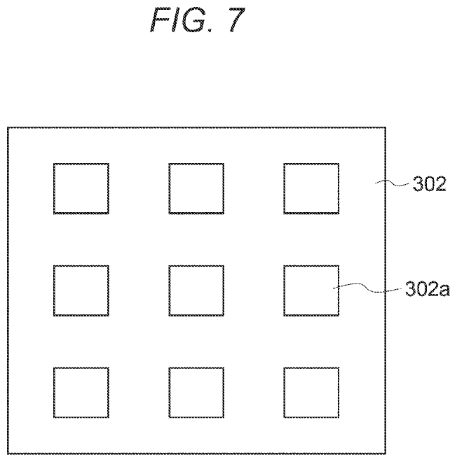

An example of a method for manufacturing the photoelectric conversion element 101 according to the present embodiment will be described with reference to FIGS. 5 to 7. FIG. 5 is a schematic view illustrating a step of generating the first second conductivity type region 35a and the second second conductivity type region 35b. FIG. 6 illustrates a plan view of a mask layer 300 used for generating the first second conductivity type region 35a. An opening 300a is formed in the mask layer 300. FIG. 7 illustrates a plan view of a mask layer 302 used for generating the second second conductivity type region 35b. An opening 302a is formed in the mask layer 302. An area of the opening 300a is formed to be larger than an area of the opening 302a.

### [Step-100]

As illustrated in FIG. 5, the first compound semiconductor layer 31 including a first compound semiconductor material having a first conductivity type, the photoelectric conversion layer 34, and the second compound semiconductor layer 32 including a second compound semiconductor material having the first conductivity type are sequentially formed. Specifically, a film formation substrate including InP and having a thickness of 0.1 μm to 1 μm is prepared. Then, the first compound semiconductor layer 31 having a thickness of 0.1 μm to 1 μm, the photoelectric conversion layer 34 having a thickness of 3 μm to 5 μm, and the second compound semiconductor layer 32 having a thickness of 0.1 μm to 1 μm are sequentially formed on the film formation substrate on the basis of a known MOCVD method.

### [Step-102]

Thereafter, as illustrated in FIG. 5, the first second conductivity type region 35a having a second conductivity type different from the first conductivity type and reaching the photoelectric conversion layer 34 is formed on at least a part of the second compound semiconductor layer 32. More specifically, the mask layer 300 (see FIG. 6) is formed on a lower surface side of the second compound semiconductor layer 32, and for example, gas phase diffusion or solid phase diffusion of impurities (specifically, zinc (Zn)) having the second conductivity type (p-type) are performed, whereby the first second conductivity type region 35a can be formed. Thereafter, the mask layer 300 is removed.

### [Step-104]

Thereafter, as illustrated in FIG. 5, the second second conductivity type region 35b having the second conductivity type and reaching the photoelectric conversion layer 34 is formed. More specifically, the mask layer 302 (see FIG. 7) is formed on the lower surface side of the second compound semiconductor layer 32, and for example, gas phase diffusion or solid phase diffusion of impurities (specifically, zinc (Zn)) having the second conductivity type (p-type) are performed, whereby the second second conductivity type region 35b can be formed. For example, a concentration of Zn in step-104 is set higher than a concentration thereof in step-102, and diffusion is performed at a higher temperature. Thereafter, the mask layer 302 is removed. As described above, in a case where a Zn diffusion region of a plurality of stages is generated, a spreading range, an impurity concentration, and the like of the Zn diffusion region of the plurality of stages can be changed by changing a shape of the mask, the impurity concentration, diffusion temperature, diffusion time, and the like.

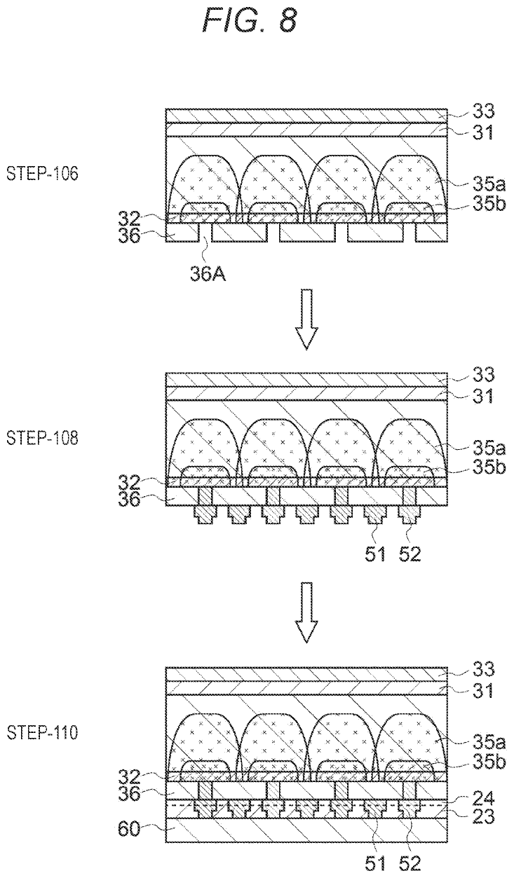

FIG. 8 is a schematic view illustrating a step of generating the first electrode 51 and the second electrode 52b.

After step-104, the second electrode 52 is formed in the second second conductivity type region 35b in step-106 to step-108. In addition, the first electrode 51 electrically connected to the first compound semiconductor layer 31 is formed

### [Step-106]

More specifically, the covering layer 36 including SiN is formed on the second second conductivity type region 35b and the second compound semiconductor layer 32, and then an opening 36A is formed in the covering layer 36 at a portion where the second electrode 52 is to be formed on the basis of a photolithography technique and an etching technique.

### [Step-108]

Next, the second electrode 52 is formed over from the top of the second conductivity type regions 35 exposed at the bottom of the opening 36A to the top of the covering layer 36, and the first electrode 51 is formed over the top of the covering layer 36.

### [Step-110]

Next, the support substrate 23 and the driving substrate 60 are bonded to each other via the insulating film 24 on the basis of a known method. In this way, the photoelectric conversion element 101 having the structure illustrated in FIG. 2 can be configured. Note that a copper layer (not illustrated) is formed as a connection portion on top surfaces of the first electrode 51 and the second electrode 52.

As described above, the photoelectric conversion element 101 according to the present embodiment is configured by the two-stage Zn diffusion such that the second second conductivity type region 35b having an impurity concentration of, for example, 1e²⁰ [cm⁻³] is formed deeper than 50 nm in the depth direction of the pixel center in the second compound semiconductor layer 32 and the photoelectric conversion layer 34, and the first second conductivity type region 35a has a concentration difference of, for example, 1e¹⁷ [cm⁻³] from the impurity concentration of the second second conductivity type region 35b. As described above, since the first second conductivity type region 35a is further formed in the photoelectric conversion element 101 according to the present embodiment, holes, which are carriers generated on the incident light side of the photoelectric conversion layer 34, can also be collected by the second electrode 52 by the electric field generated at the boundary of the first second conductivity type region 35a, and color mixture between pixels can be further suppressed.

### Second Embodiment

A photoelectric conversion element 101 of an imaging device 100 according to a second embodiment is different from the imaging device 100 according to the first embodiment in that the photoelectric conversion element 101 further includes a third second conductivity type region 35c by three-stage impurity diffusion. Differences from the imaging device 100 according to the first embodiment will be described below.

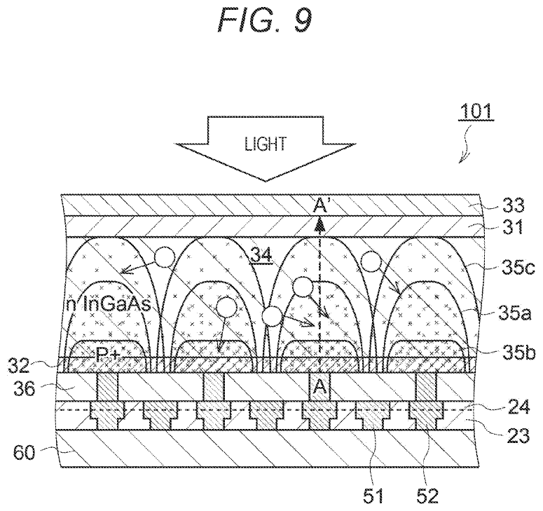

FIG. 9 is a schematic partial cross-sectional view of the photoelectric conversion element 101 according to the second different from the photoelectric conversion element 101 according to the first embodiment in further including the third second conductivity type region 35c.

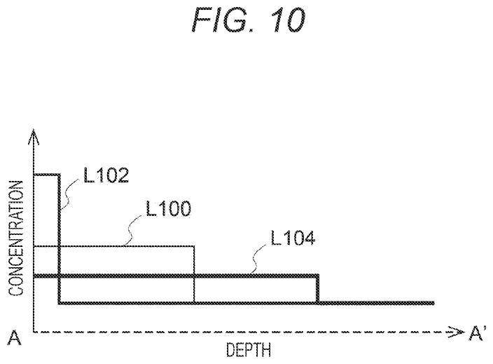

FIG. 10 is a diagram illustrating a relationship between positions and concentrations of a first second conductivity type region 35a, a second second conductivity type region 35b, and the third second conductivity type region 35c. The vertical axis represents concentration, and the horizontal axis represents a position on an A-A′ line (see FIG. 9). A position of a lower surface of a second compound semiconductor layer 32 is indicated by 0 as a Zn diffusion surface, and a position from the Zn diffusion surface is indicated as a depth. A line L100 indicates a relationship between a depth and an impurity concentration of the first second conductivity type region 35a. A line L102 indicates a relationship between a depth and an impurity concentration of the second second conductivity type region 35b. A line L104 indicates a relationship between a depth and an impurity concentration of the third second conductivity type region 35c. In this manner, the first second conductivity type region 35a, the second second conductivity type region 35b, and the third second conductivity type region 35c are formed by three-stage Zn diffusion.

When infrared light is incident on the photoelectric conversion element 101 from a first compound semiconductor layer 31 side, holes and electrons are generated in a photoelectric conversion layer 34. When a potential higher than that of a second electrode 52 is applied to a first electrode 51, the electrons are extracted from the first conductivity type region 31 to the outside via the first electrode 51. On the other hand, the holes are extracted from the third second conductivity type region 35c, the first second conductivity type region 35a, the second second conductivity type region 35b, and the second compound semiconductor layer 32 to the outside via the second electrode 52. Since an electric field is generated at a boundary where a Z concentration difference occurs, more holes as carriers can be collected by the second electrode 52 by the third second conductivity type region 35c, the first second conductivity type region 35a, and the second second conductivity type region 35b.

As described above, since the third second conductivity type region 35c is further formed in the photoelectric conversion element 101 according to the present embodiment, holes, which are carriers generated on the incident light side of the photoelectric conversion layer 34, can also be collected by the second electrode 52 by the electric field generated at the boundary of the third second conductivity type region 35c, and color mixing can be further suppressed. That is, the formation of the electric field can be generated such that more carriers (for example, the holes) are collected by the second electrode 52 by forming the second conductivity type regions 35a, 35b, 35c in three stages. Therefore, carriers generated in a predetermined range (corresponding to a pixel range) above the second electrode 52 can be collected by the second electrode 52 in the same pixel.

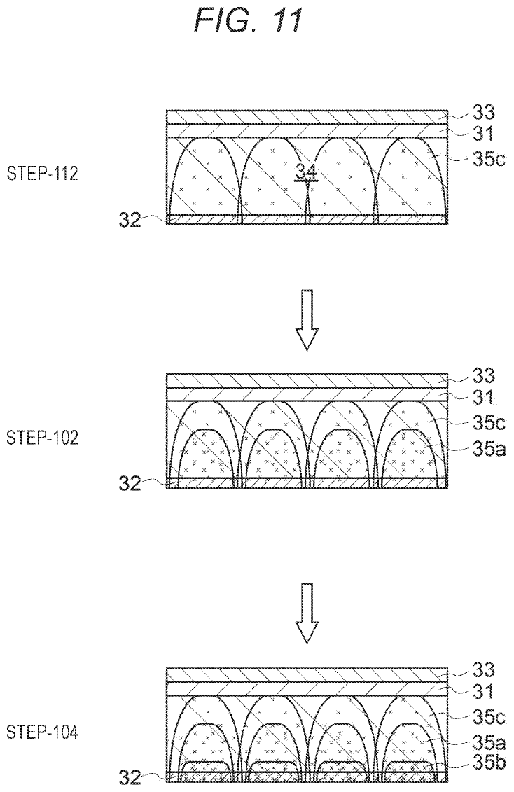

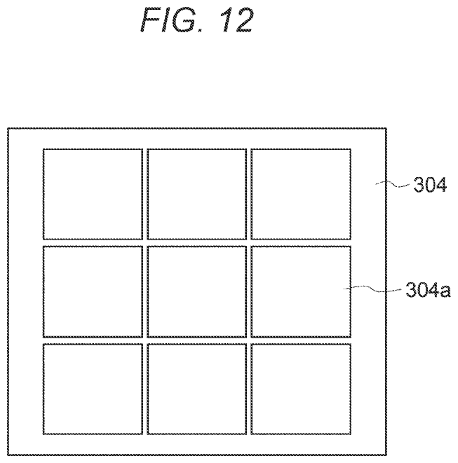

An example of a method for manufacturing the photoelectric conversion element 101 according to the second embodiment will be described with reference to FIGS. 11 and 12. FIG. 11 is a schematic view illustrating a step of generating the third second conductivity type region 35c, the first second conductivity type region 35a, and the second second conductivity type region 35b. FIG. 12 is a plan view of a mask layer 304 used for generating the third second conductivity type region 35c. An opening 304a is formed in the mask layer 304. An area of the opening 304a is formed to be larger than the area of the opening 300a (see FIG. 6). As shown in FIG. 11, step-112 is performed between step-100 (see FIG. 5) and step-102 (see FIG. 5). Note that step-106 to step-108 are equivalent to those described above, and thus description thereof is omitted.

### [Step-112]

As illustrated in FIG. 11, the third second conductivity type region 35c having a second conductivity type different from the first conductivity type and reaching the photoelectric conversion layer 34 is formed on at least a part of the second compound semiconductor layer 32. More specifically, the mask layer 304 (see FIG. 10) is formed on a lower surface side of the second compound semiconductor layer 32, and for example, gas phase diffusion or solid phase diffusion of impurities (specifically, zinc (Zn)) having the second conductivity type (p-type) are performed, whereby the third second conductivity type region 35c can be formed. Thereafter, the mask layer 300 is removed. Thereafter, steps similar to step-102 (see FIG. 5) and step-104 (see FIG. 5) are performed. Note that, in a case where a Zn diffusion region of a plurality of stages is generated, a spreading range, an impurity concentration, and the like of the Zn diffusion region of the plurality of stages can be adjusted by changing a shape of the mask, the impurity concentration, diffusion temperature, diffusion time, and the like.

As described above, in the photoelectric conversion element 101 according to the present embodiment, the first second conductivity type region 35a, the second second conductivity type region 35b, and the third second conductivity type region 35c are formed by the three-stage Zn diffusion. Since the third second conductivity type region 35c is further formed, more holes, which are carriers generated on the incident light side of the photoelectric conversion layer 34, can also be collected by the second electrode 52 by the electric field generated at the boundary of the first second conductivity type region 35a, and color mixing can be further suppressed. Therefore, carriers generated in a predetermined range (corresponding to a pixel range) above the second electrode 52 can be collected by the second electrode 52 in the same pixel.

### Third Embodiment

A photoelectric conversion element 101 of an imaging device 100 according to a third embodiment is different from the imaging device 100 according to the first embodiment in that the photoelectric conversion element 101 performs two-stage Zn diffusion from different places. Differences from the imaging device 100 according to the first embodiment will be described below.

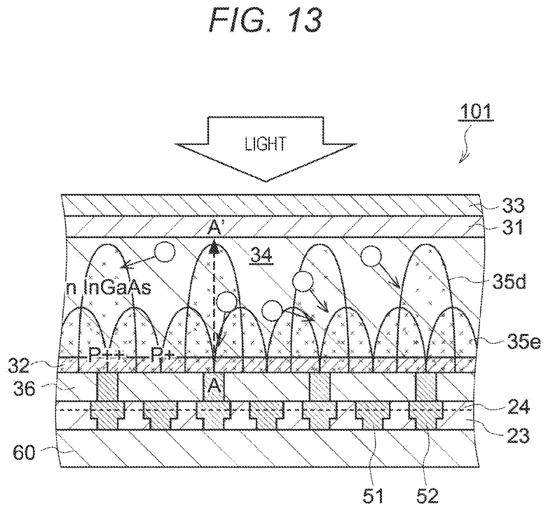

FIG. 13 is a schematic partial cross-sectional view of the photoelectric conversion element 101 according to the third different from the photoelectric conversion element 101 according to the first embodiment in including a fourth second conductivity type region 35d and a fifth second conductivity type region 35e in which Zn diffusion is performed from a different position.

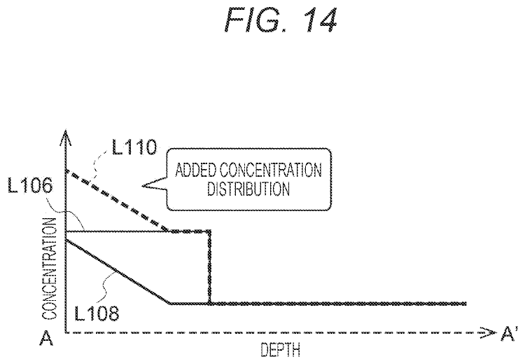

FIG. 14 is a diagram illustrating a relationship between positions and concentrations of the fourth second conductivity type region 35d and the fifth second conductivity type region 35e. The vertical axis represents concentration, and the horizontal axis represents a position on an A-A′ line (see FIG. 13). A position of a lower surface of a second compound semiconductor layer 32 is indicated by 0 as a Zn diffusion surface, and a position from the Zn diffusion surface is indicated as a depth. A line L106 indicates a relationship between a depth and an impurity concentration of the fourth second conductivity type region 35d. A line L108 indicates a relationship between a depth and an impurity concentration of the fifth second conductivity type region 35e. A line L110 indicates a concentration obtained by adding the concentrations of the fourth second conductivity type region 35d and the fifth second conductivity type region 35e. In this way, by performing Zn diffusion from different places, it is possible to more freely set a concentration distribution, that is, an electric field. For example, it is also possible to form a region where the concentration distribution in the depth direction is continuously reduced. As described above, by performing Zn diffusion from different places, it is possible to more freely set a spread of the concentration distribution, that is, the electric field, and it is possible to form an electric field that further prevents color mixture.

When infrared light is incident on the photoelectric conversion element 101 from a first compound semiconductor layer 31 side, holes and electrons are generated in a photoelectric conversion layer 34. When a potential higher than that of a second electrode 52 is applied to a first electrode 51, the electrons are extracted to the outside via the first electrode 51. On the other hand, the holes are extracted from the fourth second conductivity type region 35d, the fifth second conductivity type region 35e, and the second compound semiconductor layer 32 to the outside via the second electrode 52.

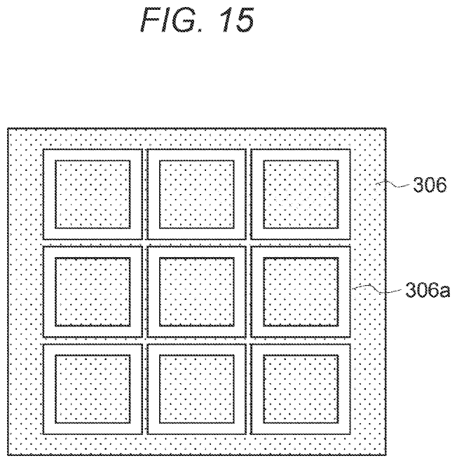

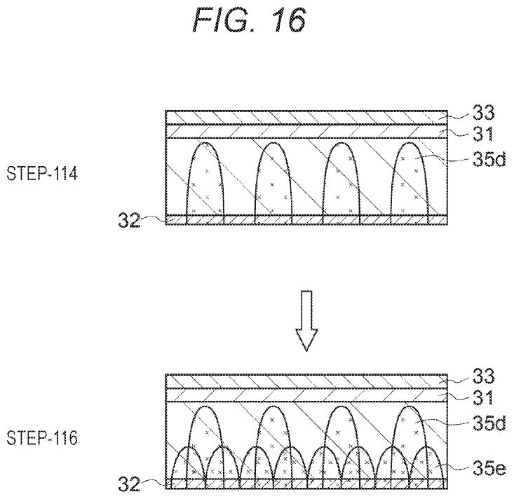

An example of a method for manufacturing the photoelectric conversion element 101 according to the third embodiment will be described with reference to FIGS. 15 and 16. FIG. 15 is a plan view of a mask layer 306 used for generating the fifth second conductivity type region 35e. FIG. 16 is a schematic view illustrating a step of generating the fourth second conductivity type region 35d and the fifth second conductivity type region 35e. A toroidal opening 306a is formed in the mask layer 306.

### [Step-114]

As illustrated in FIG. 16, the fourth second conductivity type region 35d having a second conductivity type different from the first conductivity type and reaching the photoelectric conversion layer 34 is formed on at least a part of the second compound semiconductor layer 32. More specifically, the mask layer 302 (see FIG. 7) is formed on the lower surface side of the second compound semiconductor layer 32, and for example, gas phase diffusion of impurities (specifically, zinc (Zn)) having the second conductivity type (p-type) are performed. In this case, the gas phase diffusion is performed in a time longer than that in step 104 (see FIG. 5). Thereafter, the mask layer 302 is removed.

### [Step-116]

As illustrated in FIG. 16, the fifth second conductivity type region 35e having a second conductivity type different from the first conductivity type and reaching the photoelectric conversion layer 34 is formed on at least a part of the second compound semiconductor layer 32. More specifically, the mask layer 306 (see FIG. 15) is formed on the lower surface side of the second compound semiconductor layer 32, and for example, gas phase diffusion of impurities (specifically, zinc (Zn)) having the second conductivity type (p-type) are performed. Thereafter, the mask layer 302 is removed. Note that, in a case where a Zn diffusion region of a plurality of stages is generated, a spreading range, an impurity concentration, and the like of the Zn diffusion region of the plurality of stages can be adjusted with a higher degree of freedom by changing the impurity concentration, diffusion temperature, diffusion time, and the like.

As described above, in the photoelectric conversion element 101 according to the present embodiment, the two-stage Zn diffusion is performed from different places, and the fourth second conductivity type region 35d and the fifth second conductivity type region 35e are formed. As described above, by performing the Zn diffusion from different places, it is possible to form the region in which the concentration distribution in the depth direction continuously decreases. Therefore, it is possible to more freely set the concentration distribution, that is, the electric field, and it is possible to form an electric field that further prevents color mixing.

### Fourth Embodiment

A photoelectric conversion element 101 of an imaging device 100 according to a fourth embodiment is different from the imaging device 100 according to the first embodiment in that Zn diffusion is performed on a photoelectric conversion layer 34 having a laminated structure in which impurity concentrations are different in advance. Differences from the imaging device 100 according to the first embodiment will be described below.

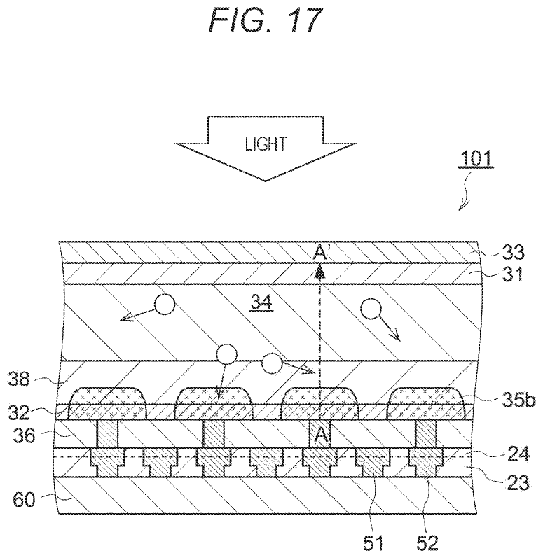

FIG. 17 is a schematic partial cross-sectional view of the photoelectric conversion element 101 according to the fourth embodiment. The photoelectric conversion layer 34 according to the fourth embodiment is different from the photoelectric conversion element 101 according to the first embodiment in further including a photoelectric conversion layer 38 with a different impurity concentration.

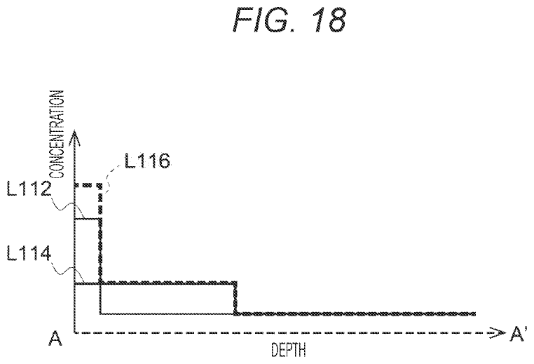

FIG. 18 is a diagram illustrating a relationship between positions and concentrations of the photoelectric conversion layer 34 having the photoelectric conversion layer 38 with the different impurity concentration and a second second conductivity type region 35b. The vertical axis represents concentration, and the horizontal axis represents a position on an A-A′ line (see FIG. 13). A position of a lower surface of a second compound semiconductor layer 32 is indicated by 0 as a Zn diffusion surface, and a position from the Zn diffusion surface is indicated as a depth. A line L114 indicates a relationship between a depth and an impurity concentration of the photoelectric conversion layer 34 including the photoelectric conversion layer 38. A line L112 indicates a relationship between a depth and an impurity concentration of the second second conductivity type region 35b. A line L116 indicates a concentration obtained by adding the concentrations of the photoelectric conversion layer 34 including the photoelectric conversion layer 38 and the second conductivity type region 35b. As described above, Zn diffusion is performed on the photoelectric conversion layer 34 having the laminated structure in which the impurity concentrations are different in advance, whereby a concentration distribution, that is, an electric field can be more freely set. Therefore, an electric field capable of further preventing color mixture between pixels can be formed.

When infrared light is incident on the photoelectric conversion element 101 from a first compound semiconductor layer 31 side, holes and electrons are generated in the photoelectric conversion layer 34. When a potential higher than that of a second electrode 52 is applied to a first electrode 51, the electrons are extracted from the first conductivity type region 31 to the outside via the first electrode 51. On the other hand, the holes are extracted from the second second conductivity type region 35b to the outside via the second electrode 52.

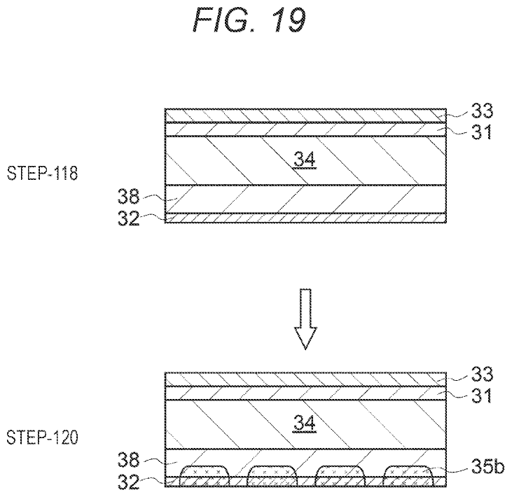

An example of a method for manufacturing the photoelectric conversion element 101 according to the fourth embodiment will be described with reference to FIG. 19. FIG. 19 is a diagram illustrating the example of the method for manufacturing the photoelectric conversion element 101 according to the fourth embodiment. Note that step-106 to step-108 (see FIG. 8) are equivalent to those described above, and thus description thereof is omitted.

### [Step-118]

As illustrated in FIG. 19, the first compound semiconductor layer 31 including a first compound semiconductor material having a first conductivity type, the photoelectric conversion layer 34, the photoelectric conversion layer 38, and the second compound semiconductor layer 32 including a second compound semiconductor material having the first conductivity type are sequentially formed. Specifically, a film formation substrate including InP and having a thickness of 0.1 μm to 1 μm is prepared. Then, the first compound semiconductor layer 31 having a thickness of 0.1 μm to 1 μm, the photoelectric conversion layer 34 having a thickness of 2 μm to 5 μm, the photoelectric conversion layer 38 having a thickness of 1 μm to 3 μm, and the second compound semiconductor layer 32 having a thickness of 0.1 μm to 1 μm are sequentially formed on the film formation substrate on the basis of a known MOCVD method.

### [Step-120]

Thereafter, as illustrated in FIG. 19, the second second conductivity type region 35b having a second conductivity type different from the first conductivity type and reaching the photoelectric conversion layer 38 is formed on at least a part of the second compound semiconductor layer 32. More specifically, the mask layer 302 (see FIG. 7) is formed on a lower surface side of the second compound semiconductor layer 32, and for example, gas phase diffusion or solid phase diffusion of impurities (specifically, zinc (Zn)) having the second conductivity type (p-type) are performed, whereby the first second conductivity type region 35a can be formed. Thereafter, the mask layer 300 is removed.

As described above, in the photoelectric conversion element 101 according to the present embodiment, the first second conductivity type region 35a is provided for the photoelectric conversion layer 34 having the laminated structure in which the impurity concentrations are different in advance. Therefore, it is possible to more freely set a concentration distribution, that is, an electric field, and it is possible to form an electric field capable of further preventing color mixing.

### Fifth Embodiment

A photoelectric conversion element 101 of an imaging device 100 according to a fifth embodiment is different from the imaging device 100 according to the first embodiment in that Zn diffusion is performed in a plurality of stages on a photoelectric conversion layer 34 having a laminated structure in which impurity concentrations are different in advance. Differences from the imaging device 100 according to the first embodiment will be described below.

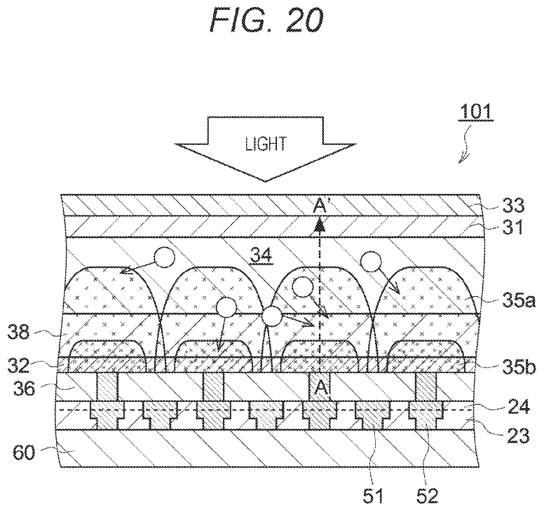

FIG. 20 is a schematic partial cross-sectional view of the photoelectric conversion element 101 according to the fifth embodiment. The photoelectric conversion layer 34 according to the fifth embodiment is different from the photoelectric conversion element 101 according to the first embodiment in further including a photoelectric conversion layer 38 having a different impurity concentration.

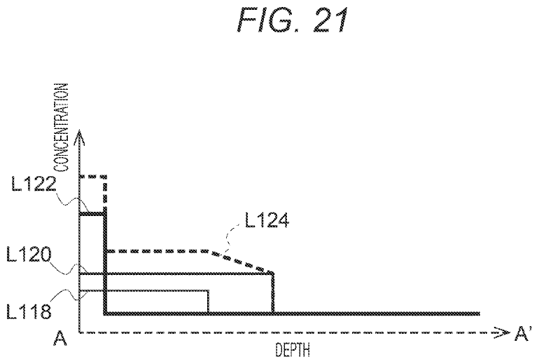

FIG. 21 is a diagram illustrating a relationship between positions and concentrations of the photoelectric conversion layer 34 having the photoelectric conversion layer 38, a first second conductivity type region 35a, and a second second conductivity type region 35b. The vertical axis represents concentration, and the horizontal axis represents a position on an A-A′ line (see FIG. 13). A position of a lower surface of a second compound semiconductor layer 32 is indicated by 0 as a Zn diffusion surface, and a position from the Zn diffusion surface is indicated as a depth. A line L118 indicates a relationship between a depth and an impurity concentration of the photoelectric conversion layer 34 including the photoelectric conversion layer 38. A line L120 indicates a relationship between a depth and an impurity concentration of the first second conductivity type region 35a. A line L122 indicates a relationship between a depth and an impurity concentration of the second second conductivity type region 35b. A line L124 indicates a concentration obtained by adding the concentrations of the photoelectric conversion layer 34 including the photoelectric conversion layer 38, the first second conductivity type region 35a, and the second second conductivity type region 35b. As described above, Zn diffusion is performed a plurality of times on the photoelectric conversion layer 34 having the laminated structure in which the impurity concentrations are different in advance, whereby a concentration distribution, that is, an electric field can be more freely set. Therefore, an electric field capable of further preventing color mixture between pixels can be formed. Note that, similarly to the second and third embodiments, the Zn diffusion may be performed in three or more stages, or the Zn diffusion may be performed by changing a shape of a mask layer.

When infrared light is incident on the photoelectric conversion element 101 from a first compound semiconductor layer 31 side, holes and electrons are generated in the photoelectric conversion layer 34. When a potential higher than that of a second electrode 52 is applied to a first electrode 51, the electrons are extracted from the first conductivity type region 31 to the outside via the first electrode 51. On the other hand, the holes are extracted from the first second conductivity type region 35 and the second second conductivity type region 35b to the outside via the second electrode 52.

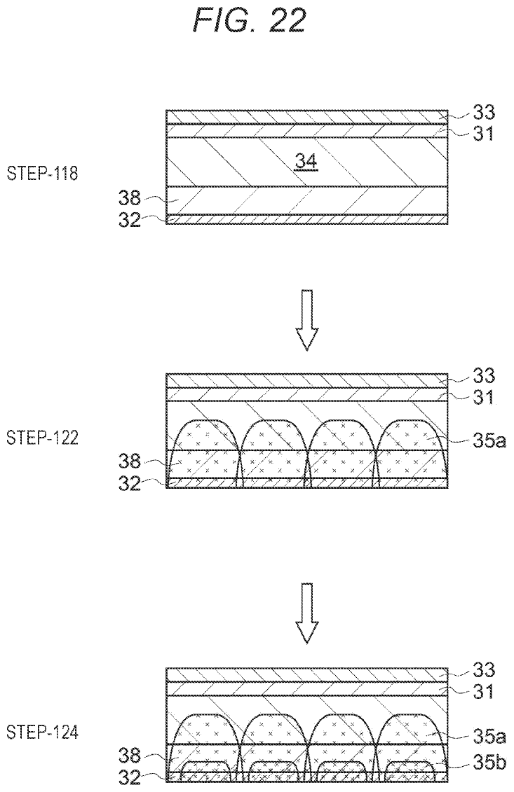

An example of a method for manufacturing the photoelectric conversion element 101 according to the fifth embodiment will be described with reference to FIG. 22. FIG. 22 is a diagram illustrating the example of the method for manufacturing the photoelectric conversion element 101 according to the fifth embodiment. Note that step-106 to step-108 (see FIG. 8) are equivalent to those described above, and thus description thereof is omitted.

After [step-118], step-122 and step-124 are performed.

### [Step-122]

Thereafter, as illustrated in FIG. 22, the first second conductivity type region 35a having a second conductivity type different from the first conductivity type and reaching the photoelectric conversion layer 34 is formed on at least a part of the second compound semiconductor layer 32. More specifically, the mask layer 300 (see FIG. 6) is formed on a lower surface side of the second compound semiconductor layer 32, and for example, gas phase diffusion or solid phase diffusion of impurities (specifically, zinc (Zn)) having the second conductivity type (p-type) are performed, whereby the first second conductivity type region 35a can be formed. Thereafter, the mask layer 300 is removed.

### [Step-124]

Thereafter, as illustrated in FIG. 22, the second second conductivity type region 35b having the second conductivity type and reaching the photoelectric conversion layer 34 is formed. More specifically, the mask layer 302 (see FIG. 7) is formed on a lower surface side of the second compound semiconductor layer 32, and for example, gas phase diffusion or solid phase diffusion of impurities (specifically, zinc (Zn)) having the second conductivity type (p-type) are performed, whereby the second second conductivity type region 35b can be formed. For example, a concentration of Zn in step-124 is set higher than a concentration thereof in step-122, and diffusion is performed at a higher temperature. Thereafter, the mask layer 302 is removed. As described above, in a case where a Zn diffusion region of a plurality of stages is generated, a spreading range, an impurity concentration, and the like of the Zn diffusion region of the plurality of stages can be changed by changing a shape of the mask, the impurity concentration, the temperature, time, and the like.

As described above, in the photoelectric conversion element 101 according to the present embodiment, the first second conductivity type region 35a and the second second conductivity type region 35b are provided for the photoelectric conversion layer 34 having the laminated structure in which the impurity concentrations are different in advance. Therefore, it is possible to more freely set a concentration distribution, that is, an electric field, and it is possible to form an electric field capable of further preventing color mixing.

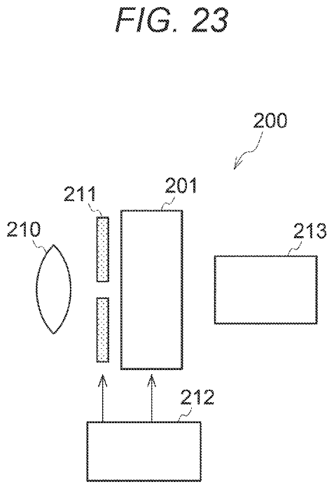

FIG. 23 is a conceptual diagram illustrating an example in which the disclosed imaging device 100 (201 in FIG. 23) is used in an electronic apparatus (camera) 200. The electronic apparatus 200 includes the imaging device 201, an optical lens 210, a shutter device 211, a drive circuit 212, and a signal processing circuit 213. The optical lens 210 forms an image of image light (incident light) from a subject on an imaging surface of the imaging device 201. With this arrangement, signal charges are accumulated in the imaging device 201 for a certain period. The shutter device 211 controls a light irradiation period and a light shielding period for the imaging device 201. The drive circuit 212 supplies a drive signal for controlling a transfer operation and the like of the imaging device 201 and a shutter operation of the shutter device 211. A signal of the imaging device 201 is transferred by a drive signal (timing signal) supplied from the drive circuit 212. The signal processing circuit 213 performs various types of signal processing. A video signal subjected to the signal processing is stored in a storage medium such as a memory and the like or output to a monitor. In such an electronic apparatus 200, pixel size can be miniaturized in the imaging device 201, and furthermore, transfer efficiency is improved, so that the electronic apparatus 200 with improved pixel characteristics can be obtained. The electronic apparatus 200 to which the imaging device 201 can be applied is not limited to the camera, and can be applied to an imaging device such as a digital still camera, a camera module for a mobile device such as a mobile phone, and the like.

Note that the present technology can also be embodied in the configurations as described below.

(1) A photoelectric conversion element including:
a first compound semiconductor layer including a first compound semiconductor material having a first conductivity type;
a photoelectric conversion layer formed in contact with the first compound semiconductor layer;
a second compound semiconductor layer formed in contact with the photoelectric conversion layer and including a second compound semiconductor material having the first conductivity type;
a first second conductivity type region formed on at least a part of the second compound semiconductor layer, having a second conductivity type different from the first conductivity type, and reaching the photoelectric conversion layer; and
a second second conductivity type region formed on at least a part of the second compound semiconductor layer, having the second conductivity type, and reaching the photoelectric conversion layer, the second second conductivity type region having a region different from the first second conductivity type region.

(2) The photoelectric conversion element according to (1), further including:
a first electrode electrically connected to the first compound semiconductor layer; and
a second electrode formed on the second conductivity type regions.

(3) The photoelectric conversion element according to (1) or (2), in which the first second conductivity type region and the second second conductivity type region have different impurity concentrations.

(4) The photoelectric conversion element according to (3), in which the first second conductivity type region has a lower impurity concentration than the second second conductivity type region, and the first second conductivity type region is formed closer to the first compound semiconductor layer than the second second conductivity type region.

(5) The photoelectric conversion element according to (4), further including:
a third second conductivity type region formed on at least a part of the second compound semiconductor layer, having the second conductivity type, and reaching the photoelectric conversion layer, the third second conductivity type region having a region different from the first second conductivity type region and the second second conductivity type region.

(6) The photoelectric conversion element according to any one of (1) to (5), in which the first second conductivity type region and the second second conductivity type region are formed by diffusing impurities under different conditions.

(7) The photoelectric conversion element according to (6), in which the first second conductivity type region and the second second conductivity type region are formed by diffusing the impurities from different positions.

(8) The photoelectric conversion element according to (7), in which the first second conductivity type region has a higher impurity concentration than the second second conductivity type region, and is formed closer to the first compound semiconductor layer than the second second conductivity type region.

(9) The photoelectric conversion element according to (8), in which the second second conductivity type region has two protruded regions along the second compound semiconductor layer.

(10) The photoelectric conversion element according to any one of (1) to (9), in which the photoelectric conversion layer is formed by laminating a plurality of layers having different impurity concentrations.

(11) The photoelectric conversion element according to (2), in which the first electrode is formed on a surface of the first compound semiconductor layer on a light incident side.

(12) The photoelectric conversion element according to any one of (1) to (11), in which the first compound semiconductor layer and the second compound semiconductor layer include the same material.

(13) The photoelectric conversion element according to (12), in which the first compound semiconductor layer and the second compound semiconductor layer include a group III-V compound semiconductor material.

(14) The photoelectric conversion element according to (13), in which the photoelectric conversion layer includes InGaAs, and the first compound semiconductor layer and the second compound semiconductor layer include InP.

(15) The photoelectric conversion element according to (1), in which light enters through the first compound semiconductor layer.

(16) An imaging device in which a plurality of the photoelectric conversion elements according to any one of (1) to (15) is arranged in a two-dimensional matrix.

(17) A method for manufacturing a photoelectric conversion element including the steps of: sequentially forming a first compound semiconductor layer including a first compound semiconductor material having a first conductivity type, a photoelectric conversion layer, and a second compound semiconductor layer including a second compound semiconductor material having the first conductivity type;
forming, on at least a part of the second compound semiconductor layer, a first second conductivity type region having a second conductivity type different from the first conductivity type and reaching the photoelectric conversion layer; and
forming, on at least a part of the second compound semiconductor layer, a second second conductivity type region having the second conductivity type and reaching the photoelectric conversion layer under a condition different from a condition of the first second conductivity type region.

(18) The method for manufacturing the photoelectric conversion element according to (17), in which the first second conductivity type region and the second second conductivity type region are formed by diffusing impurities from the second compound semiconductor layer via a mask layer.

(19) The method for manufacturing the photoelectric conversion element according to (18), in which the second second conductivity type region is formed by diffusing impurities from the second compound semiconductor layer via a first mask layer, removing the first mask layer, and then diffusing impurities via a second mask layer.

(20) The method for manufacturing the photoelectric conversion element according to (19), in which a state in which the impurities are diffused via the first mask layer is different from a state in which the impurities are diffused via the second mask layer in at least any one of an impurity concentration, a temperature, and a time.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

31 First compound semiconductor layer
32 Second compound semiconductor layer
34 Photoelectric conversion layer
35a to 35e Second conductivity type region
51 First electrode
52 Second electrode
60 Driving substrate
100 Imaging device
101 Photoelectric conversion element (imaging element).

1. A photoelectric conversion element comprising:
a first compound semiconductor layer including a first compound semiconductor material having a first conductivity type;
a photoelectric conversion layer formed in contact with the first compound semiconductor layer;
a second compound semiconductor layer formed in contact with the photoelectric conversion layer and including a second compound semiconductor material having the first conductivity type;
a first second conductivity type region formed on at least a part of the second compound semiconductor layer, having a second conductivity type different from the first conductivity type, and reaching the photoelectric conversion layer; and
a second second conductivity type region formed on at least a part of the second compound semiconductor layer, having the second conductivity type, and reaching the photoelectric conversion layer, the second second conductivity type region having a region different from the first second conductivity type region.

2. The photoelectric conversion element according to claim 1, further comprising:
a first electrode electrically connected to the first compound semiconductor layer; and
a second electrode formed on the second conductivity type regions.

3. The photoelectric conversion element according to claim 1, wherein the first second conductivity type region and the second second conductivity type region have different impurity concentrations.

4. The photoelectric conversion element according to claim 3, wherein the first second conductivity type region has a lower impurity concentration than the second second conductivity type region, and the first second conductivity type region is formed closer to the first compound semiconductor layer than the second second conductivity type region.

5. The photoelectric conversion element according to claim 4, further comprising:
a third second conductivity type region formed on at least a part of the second compound semiconductor layer, having the second conductivity type, and reaching the photoelectric conversion layer, the third second conductivity type region having a region different from the first second conductivity type region and the second second conductivity type region.

6. The photoelectric conversion element according to claim 1, wherein the first second conductivity type region and the second second conductivity type region are formed by diffusing impurities under different conditions.

7. The photoelectric conversion element according to claim 6, wherein the first second conductivity type region and the second second conductivity type region are formed by diffusing the impurities from different positions.

8. The photoelectric conversion element according to claim 7, wherein the first second conductivity type region has a higher impurity concentration than the second second conductivity type region, and is formed closer to the first compound semiconductor layer than the second second conductivity type region.

9. The photoelectric conversion element according to claim 8, wherein the second second conductivity type region has two protruded regions along the second compound semiconductor layer.

10. The photoelectric conversion element according to claim 1, wherein the photoelectric conversion layer is formed by laminating a plurality of layers having different impurity concentrations.

11. The photoelectric conversion element according to claim 2, wherein the first electrode is formed on a surface of the first compound semiconductor layer on a light incident side.

12. The photoelectric conversion element according to claim 1, wherein the first compound semiconductor layer and the second compound semiconductor layer include a same material.

13. The photoelectric conversion element according to claim 12, wherein the first compound semiconductor layer and the second compound semiconductor layer include a group III-V compound semiconductor material.

14. The photoelectric conversion element according to claim 13, wherein the photoelectric conversion layer includes InGaAs, and
the first compound semiconductor layer and the second compound semiconductor layer include InP.

15. The photoelectric conversion element according to claim 1, wherein light enters through the first compound semiconductor layer.

16. An imaging device in which a plurality of the photoelectric conversion elements according to claim 1 is arranged in a two-dimensional matrix.

17. A method for manufacturing a photoelectric conversion element comprising the steps of:
sequentially forming a first compound semiconductor layer including a first compound semiconductor material having a first conductivity type, a photoelectric conversion layer, and a second compound semiconductor layer including a second compound semiconductor material having the first conductivity type;
forming, on at least a part of the second compound semiconductor layer, a first second conductivity type region having a second conductivity type different from the first conductivity type and reaching the photoelectric conversion layer; and
forming, on at least a part of the second compound semiconductor layer, a second second conductivity type region having the second conductivity type and reaching the photoelectric conversion layer under a condition different from a condition of the first second conductivity type region.

18. The method for manufacturing the photoelectric conversion element according to claim 17, wherein the first second conductivity type region and the second second conductivity type region are formed by diffusing impurities from the second compound semiconductor layer via a mask layer.

19. The method for manufacturing the photoelectric conversion element according to claim 18, wherein the second second conductivity type region is formed by diffusing impurities from the second compound semiconductor layer via a first mask layer, removing the first mask layer, and then diffusing impurities via a second mask layer.

20. The method for manufacturing the photoelectric conversion element according to claim 19, wherein a state in which the impurities are diffused via the first mask layer is different from a state in which the impurities are diffused via the second mask layer in at least any one of an impurity concentration, a temperature, and a time.
